(19) United States
(12) Patent Application Publication
(10) Pub. No.: US 2026/0369955 A1
(43) Pub. Date: Nov. 19, 2026

(54) LIGHT EMITTING APPARATUS

(71) Applicant: SONY GROUP CORPORATION, TOKYO (JP)

(72) Inventors: HISAYOSHI MOTOBAYASHI, TOKYO (JP); YOSHIRO TAKIGUCHI, TOKYO (JP)

(21) Appl. No.: 19/148,143

(22) PCT Filed: Jan. 11, 2024
(86) PCT No.: PCT/JP2024/000458

§ 371 Date: Jul. 15, 2025

(30) Foreign Application Priority Data
Jan. 23, 2023 (JP) 2023-008104

(51) Int. Cl. H01S 5/02208; H01S 5/02315; H01S 5/024

(52) U.S. Cl. CPC H01S 5/02208; H01S 5/02315; H01S 5/02476

(57) ABSTRACT

A light emitting apparatus is provided that is superior in manufacturability while being small in size. The light emitting apparatus includes: a base including a support part that includes a support surface; a light emitting device provided on the base; a cover part provided on the support part to cover the light emitting device, and including an opposed part opposed to the support part and a light transmissive part that transmits light emitted from the light emitting device; and a bonding member interposed between the support part and the opposed part and bonding the support part and the opposed part to each other. The bonding member includes a first part having a first thickness and a second part having a second thickness larger than the first thickness. The light emitting apparatus has a gap between at least a portion of the second part and at least one of the support part or the opposed part.

### TECHNICAL FIELD

The present disclosure relates to a light emitting apparatus.

### BACKGROUND ART

As a light emitting apparatus including a semiconductor laser, a packaged light emitting apparatus such as a CAN package or a frame package is widely used. For example, in a light emitting apparatus described in PTL 1, a semiconductor laser is mounted in landscape orientation on a base part, and a glass cap that forms a sealing space is so coupled to the base part as to cover the semiconductor laser. Owing to having such a configuration, the light emitting apparatus described in PTL 1 achieves high airtightness while being small in size.

### CITATION LIST

### Patent Literature

PTL 1: International Publication No. WO 2017/149573A1

### SUMMARY OF THE INVENTION

Meanwhile, finer dimensions are demanded in a field of such a light emitting apparatus.

It is therefore desirable to provide a light emitting apparatus that is superior in manufacturability while being small in size.

A light emitting apparatus according to one embodiment of the present disclosure includes: a base including a support part that includes a support surface; a light emitting device provided on the base; a cover part provided on the support part to cover the light emitting device, and including an opposed part opposed to the support part and a light transmissive part that transmits light emitted from the light emitting device; and a bonding member interposed between the support part and the opposed part and bonding the support part and the opposed part to each other. The bonding member includes a first part having a first thickness and a second part having a second thickness larger than the first thickness. The light emitting apparatus has a gap between at least a portion of the second part and at least one of the support part or the opposed part.

The light emitting apparatus according to one embodiment of the present disclosure has a structure that is suitable for miniaturization and easily manufacturable.

### BRIEF DESCRIPTION OF THE DRAWINGS

FIG. 1 is a perspective diagram illustrating an exemplary outer appearance of a light emitting apparatus according to one embodiment of the present disclosure.

FIG. 2 is a first cross-sectional diagram illustrating an exemplary cross-sectional configuration of the light emitting apparatus illustrated in FIG. 1.

FIG. 3A is an enlarged cross-sectional diagram illustrating, in an enlarged manner, a partial cross-sectional configuration of the light emitting apparatus illustrated in FIG. 2.

FIG. 3B is an enlarged cross-sectional diagram illustrating, in an enlarged manner, a partial cross-sectional configuration of a first modification example of the light emitting apparatus (a first modification example of the present disclosure) illustrated in FIG. 2.

FIG. 3C is an enlarged cross-sectional diagram illustrating, in an enlarged manner, a partial cross-sectional configuration of a second modification example of the light emitting apparatus (a second modification example of the present disclosure) illustrated in FIG. 2.

FIG. 4 is a planar diagram illustrating an exemplary planar configuration of a layer including a bonding member illustrated in FIG. 1.

FIG. 5 is a second cross-sectional diagram illustrating an exemplary cross-sectional configuration of the light emitting apparatus illustrated in FIG. 1.

FIG. 6A is a schematic diagram describing a step of a manufacturing method of the light emitting apparatus illustrated in FIG. 1.

FIG. 6B is a schematic diagram describing a step subsequent to FIG. 6A.

FIG. 6C is a schematic diagram describing a step subsequent to FIG. 6B.

FIG. 6D is a schematic diagram describing a step subsequent to FIG. 6C.

FIG. 7 is a schematic diagram illustrating, in an enlarged manner, an exemplary partial cross-sectional configuration of a light emitting apparatus as a reference example.

FIG. 8 is an enlarged cross-sectional diagram illustrating a partial enlarged view of a light emitting apparatus according to a modification example of one embodiment of the present disclosure (a third modification example of the present disclosure).

FIG. 9 is an enlarged cross-sectional diagram illustrating a partial enlarged view of a light emitting apparatus according to a modification example of one embodiment of the present disclosure (a fourth modification example of the present disclosure).

FIG. 10 is an enlarged cross-sectional diagram illustrating a partial enlarged view of a light emitting apparatus according to a modification example of one embodiment of the present disclosure (a fifth modification example of the present disclosure).

FIG. 11 is a cross-sectional diagram illustrating a light emitting apparatus according to a sixth modification example of the present disclosure.

### MODES FOR CARRYING OUT THE INVENTION

In the following, some embodiments of the present disclosure will be described in detail with reference to the drawings. It is to be noted that the embodiments described below are specific examples of the present disclosure, and the present disclosure is not limited to the following embodiments. In addition, the arrangement, dimensions, dimension ratios, and the like of components in the present disclosure are not limited to the embodiment illustrated in each drawing.

The description will be given in the following order.
1. One Embodiment
1.1. Configuration Example of Light Emitting Apparatus
1.2. Manufacturing Method of Light Emitting Apparatus
1.3. Working and Effects
1.4. Modification Examples
2. Other Modification Examples

### 1. One Embodiment

### 1.1. Configuration of Light Emitting Apparatus

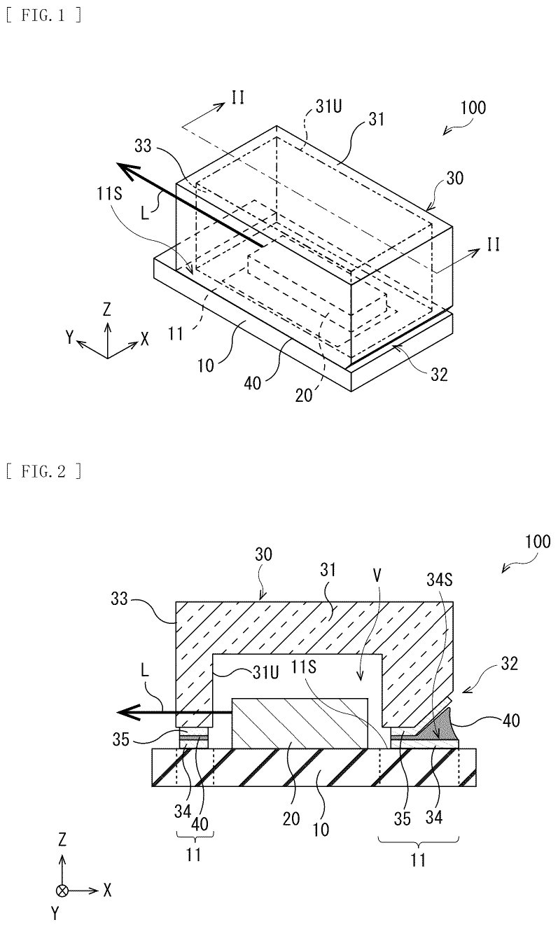

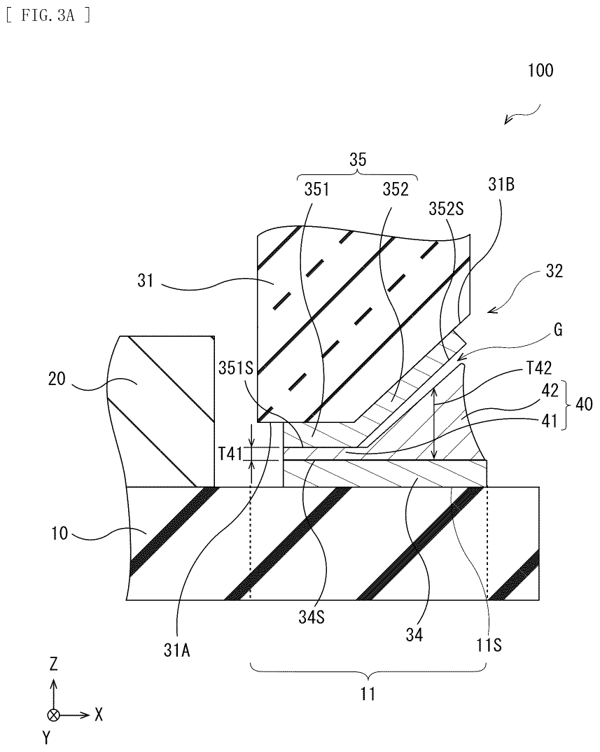

A description will be given of a specific configuration example of a light emitting apparatus 100 according to an embodiment of the present disclosure with reference to FIGS. 1 and 2. FIG. 1 is a perspective diagram illustrating an exemplary outer appearance of the light emitting apparatus 100. FIG. 2 is a cross-sectional diagram illustrating an exemplary cross-sectional configuration of the light emitting apparatus 100. FIG. 2 illustrates a cross section in an arrowed direction along line II-II illustrated in FIG. 1.

The light emitting apparatus 100 includes a base substrate 10 as a base, a semiconductor laser 20 as a light emitting device, a cap 30 as a cover part, and a bonding member 40.

The base substrate 10 is a plate-shaped member having a substantially rectangular parallelepiped outer shape. Note that the outer shape of the base substrate 10 is not limited thereto, and may be, for example, a circular plate shape, or a shape with projections and depressions. Examples of a constituent material of the base substrate 10 may include a ceramic material such as aluminum nitride (AlN) or aluminum oxide (AlOx) and a metal material such as stainless steel. As illustrated in, for example, FIG. 1, the base substrate 10 includes a support part 11 having a surface 11S. The support part 11 includes a first metal layer 34, as illustrated in FIG. 2.

The semiconductor laser 20 is provided on the base substrate 10. Note that another member such as a submount may be provided between the base substrate 10 and the semiconductor laser 20. The semiconductor laser 20 is, for example, an edge emission type laser device, and is so mounted as to extend in a major-axis direction of the base substrate 10 (a Y-axis direction), for example. The semiconductor laser 20 is set to oscillate laser light L in a +Y direction, for example, when supplied with electric power. Note that a specific configuration of the semiconductor laser 20, a wavelength range of the laser light L to be oscillated, etc. are not particularly limited, and may be freely chosen.

The cap 30 is placed on the base substrate 10. The cap 30 includes a body 31. The body 31 includes an opposed part 32, a light transmissive part 33, and a recessed part 31U. The body 31 has, for example, a substantially rectangular parallelepiped outer shape, and is so bonded to the surface 11S of the support part 11 of the base substrate 10 as to cover the semiconductor laser 20. The semiconductor laser 20 is contained in a space V surrounded by the cap 30 and the base substrate 10. Note that the space V may be sealed by the bonding member 40 that bonds the cap 30 and the base substrate 10 to each other. In such a case, the semiconductor laser 20 is sealed in the space V in which high airtightness is maintained. Note that the space V may communicate with a space outside the light emitting apparatus 100.

As illustrated in FIGS. 1 and 2, the laser light L emitted from the semiconductor laser 20 passes through the light transmissive part 33 and exits to outside the light emitting apparatus 100. Of the body 31, at least the light transmissive part 33 includes a light transmissive material, such as a glass material, that allows the laser light L oscillated by the semiconductor laser 20 to pass therethrough. The body 31 may entirely include the light transmissive material. At least the light transmissive part 33 of the body 31 may include a light transmissive material other than the glass material. Using the glass material or sapphire as a constituent material of the light transmissive part 33 makes it possible to efficiently extract the laser light L oscillated by the semiconductor laser 20 from the light transmissive part 33 to outside the light emitting apparatus 100. Note that the body 31 is not limited to a material having a high transmittance to visible light. For example, in a case where infrared light is to be oscillated as the laser light L by the semiconductor laser 20, the light transmissive part 33 of the body 31 may include chalcogenide glass or the like that exhibits a higher transmittance in an infrared light range than in a visible light range.

The opposed part 32 is a part, of the cap 30, that is opposed to the support part 11 of the base substrate 10. The opposed part 32 is provided at a position in the cap 30 that is off an optical path along which the laser light L oscillated from the semiconductor laser 20 travels. The opposed part 32 includes a second metal layer 35. The second metal layer 35 is opposed to the first metal layer 34 of the support part 11 with the bonding member 40 interposed therebetween. The first metal layer 34 and the second metal layer 35 are, for example, single-layer films each including a metal such as Au (gold), Ag (silver), Cu (copper), or Al (aluminum). The first metal layer 34 and the second metal layer 35 are each not limited to the single-layer film, and may each be a stacked film including Ti/Pt/Au or the like in which a Ti (titanium) layer, a Pt (platinum) layer, and an Au (gold) layer are stacked in this order from a side of the body 31, for example. Further usable is a single-layer film or a stacked film that includes a metal material containing a metal element other than the above.

The bonding member 40 is interposed between the support part 11 and the opposed part 32, and bonds the support part 11 and the opposed part 32 to each other. In the light emitting apparatus 100, the bonding member 40 is provided between the first metal layer 34 and the second metal layer 35, and the bonding member 40 bonds the first metal layer 34 and the second metal layer 35 to each other. The bonding member 40 includes solder, a resin adhesive, or an electrically-conductive adhesive. Examples of the solder may include AuSn, SnAgCu, and SnBi. The electrically-conductive adhesive is, for example, an Ag (silver) paste. Alternatively, a low-melting-point glass having a melting point of, for example, 600 °C or lower may be used as the bonding member 40. Further, a coefficient of thermal linear expansion (CTE) of the bonding member 40 is higher than a coefficient of thermal linear expansion of the cap 30. The coefficient of thermal linear expansion of the cap 30 referred to herein is, for example, a coefficient of thermal linear expansion of the body 31 or a coefficient of thermal linear expansion of the first metal layer 34.

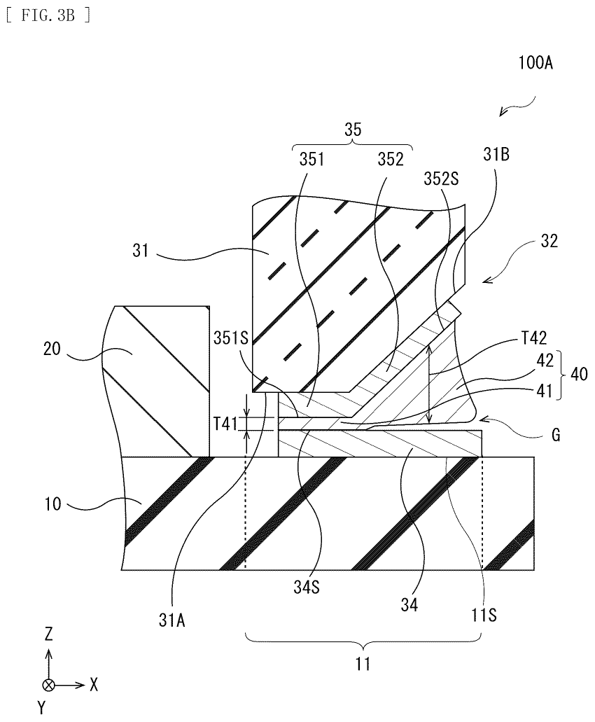

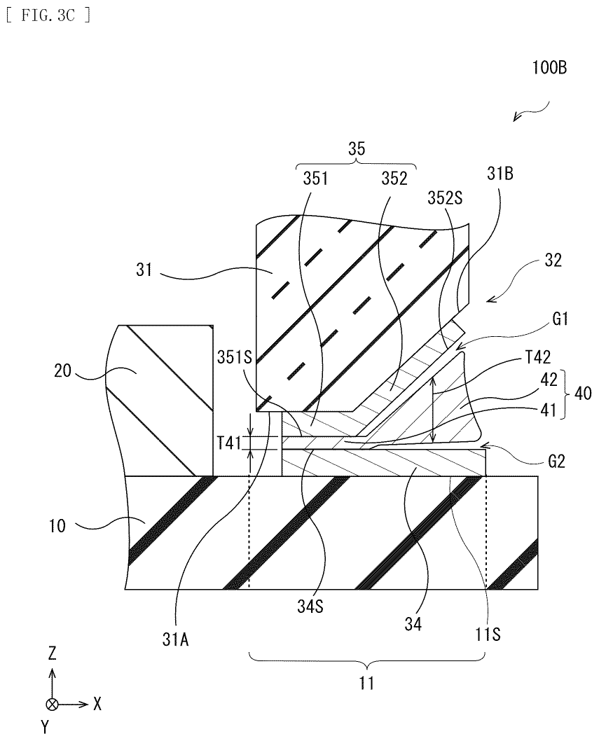

Next, a description will be given of a detailed configuration of a vicinity of the opposed part 32 with reference to FIG. 3A. FIG. 3A is an enlarged cross-sectional diagram illustrating a partial enlarged view of the light emitting apparatus 100 illustrated in FIG. 2.

As illustrated in FIG. 3A, the first metal layer 34 is provided on the surface 11S of the support part 11. The first metal layer 34 has a surface 34S as a support surface. The opposed part 32 of the body 31 includes a surface 31A extending along the surface 34S and a surface 31B inclined with respect to the surface 31A. The surface 31B forms an angle of, for example, 45 ° with respect to the surface 31A. The surface 31A and the surface 31B are provided at positions in the cap 30 that are off the optical path along which the laser light L from the semiconductor laser 20 travels. Further, the second metal layer 35 of the opposed part 32 includes a first part 351 covering the surface 31A and a second part 352 covering the surface 31B. The first part 351 has a surface 351S as an opposing surface. The surface 351S extends, for example, substantially parallel to both the surface 34S and the surface 31A along both the surface 34S and the surface 31A. The second part 352 has a surface 352S as an inclined surface inclined with respect to the surface 351S. The surface 352S extends along the surface 351S; therefore, the surface S352S is inclined with respect to the surface 34S. Accordingly, a distance between the surface 351S and the surface 34S in a Z-axis direction is substantially constant, whereas a distance between the surface 352S and the surface 34S in the Z-axis direction gradually increases toward an outer side of the cap 30, that is, with increasing distance from the first part 351 along an X-axis direction.

As illustrated in FIG. 3A, the bonding member 40 includes a first part 41 interposed between the first metal layer 34 and the first part 351 of the second metal layer 35, and a second part 42 interposed between the first metal layer 34 and the second part 352 of the second metal layer 35. The second part 42 includes a portion having a thickness T42 larger than a thickness T41 of the first part 41. In an example illustrated in FIG. 3A, the first part 41 has the thickness T41 that is substantially constant, and the second part 42 has the thickness T42 that gradually increases with increasing distance from the first part 41 along the X-axis direction. Note that the thickness refers to a dimension in the Z-axis direction. Here, a gap G is present between at least a portion of the second part 42 and at least one of the first metal layer 34 of the support part 11 or the second part 352 of the second metal layer 35 of the opposed part 32. In the example illustrated in FIG. 3A, the gap G is present between the second part 42 and the second part 352. In other words, the second part 42 and the surface 352S of the second part 352 are spaced from each other. Note that the present disclosure is not limited to an embodiment in which all of the surface 352S is spaced from the second part 42, and may include an embodiment in which only a portion of the surface 352S is spaced from the second part 42. In addition, the present disclosure may include an embodiment in which the gap G is present between the second part 42 and the first metal layer 34, as in a light emitting apparatus 100A illustrated in FIG. 3B, for example. In the embodiment of FIG. 3B, the second part 42 and the surface 34S of the first metal layer 34 are spaced from each other. Furthermore, the present disclosure may include an embodiment in which a gap G1 is present between the second part 42 and the second part 352 and a gap G2 is also present between the second part 42 and the first metal layer 34, as in a light emitting apparatus 100B illustrated in FIG. 3C, for example. In the embodiment of FIG. 3C, the second part 42 and the surface 352S are spaced from each other, and the second part 42 and the surface 34S of the first metal layer 34 are spaced from each other.

Here, wettability of the surface 352S of the second part 352 for the bonding member 40 is lower than wettability of the surface 351S of the first part 351 for the bonding member 40. Alternatively, a portion, of the surface 34S of the first metal layer 34, that is opposed to the second part 42 of the bonding member 40 may be lower in wettability for the bonding member 40 than a portion, of the surface 34S of the first metal layer 34, that is opposed to the first part 41 of the bonding member 40. To reduce the wettability of the surface 352S of the second part 352 or the wettability of the portion of the surface 34S of the first metal layer 34, it is preferable to perform surface modification treatment, for example. Specifically, corona treatment, plasma treatment, frame treatment, chemical treatment, UV irradiation, or the like may be performed as the surface modification treatment on the surface 352S of the second metal layer 35.

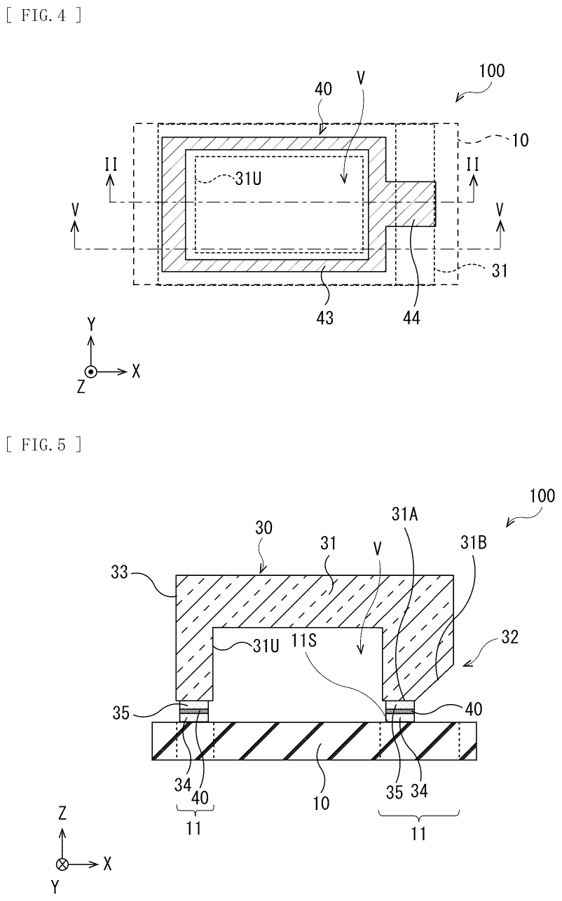

FIG. 4 is a planar diagram illustrating an exemplary planar configuration along an XY plane of a layer including the bonding member 40. As illustrated in FIG. 4, the bonding member 40 includes a surround part 43 that makes a round in the XY plane to enclose the recessed part 31U of the body 31, and a lead-out part 44 extending from the surround part 43 to outside the body 31. Owing to the bonding member 40 having the surround part 43, the cap 30 is bonded to the support part 11 of the base substrate 10 without any gap therebetween, thereby forming the space V that is sealed. Note that in a case where the space V does not have to be sealed, a gap such as a cutout may be present in a portion of the surround part 43. In a process of manufacturing the cap 30, the second metal layer 35 and the bonding member 40 are collectively formed on the opposed parts 32 of a plurality of bodies 31 in succession in a state where the bodies 31 are integral with each other before being separated from each other. The second metal layer 35 and the bonding member 40 may be formed by, for example, an electrolytic plating method. Specifically, the second metal layer 35 serves as an underlayer for plating, and the bonding member 40 is formed by electrolytic plating using the second metal layer 35 as the underlayer for plating. The lead-out part 44 is a part coupling the bonding members 40 formed on the opposed parts 32 of the plurality of bodies 31 adjacent to each other.

As illustrated in FIG. 2, the lead-out part 44 is the second part 42 having a relatively large thickness. Note that FIG. 2 corresponds to a cross section in the arrowed direction along line II-II illustrated in FIG. 4. In contrast, as illustrated in FIG. 5, at a location where no lead-out part 44 is present, no second metal layer 35 is provided on the inclined surface 31B of the body 31, and no bonding member 40 is present thereon, either. In other words, the second metal layer 35 is provided only on the surface 31A of the body 31. Further, the opposed part 32 of the body 31 includes the surface 31B inclined with respect to the surface 31A extending along the surface 34S. This suppresses an occurrence of chipping of the bonding member 40 at an end face including the lead-out part 44 when an outer edge of the body 31 is subjected to machining with, for example, a dicing blade in the manufacturing process.

### 1.2. Manufacturing Method of Light Emitting Apparatus

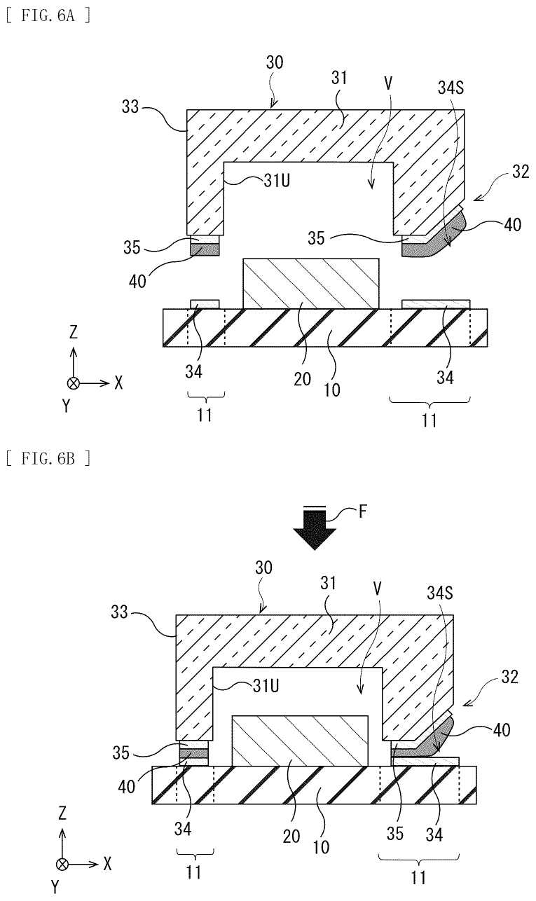

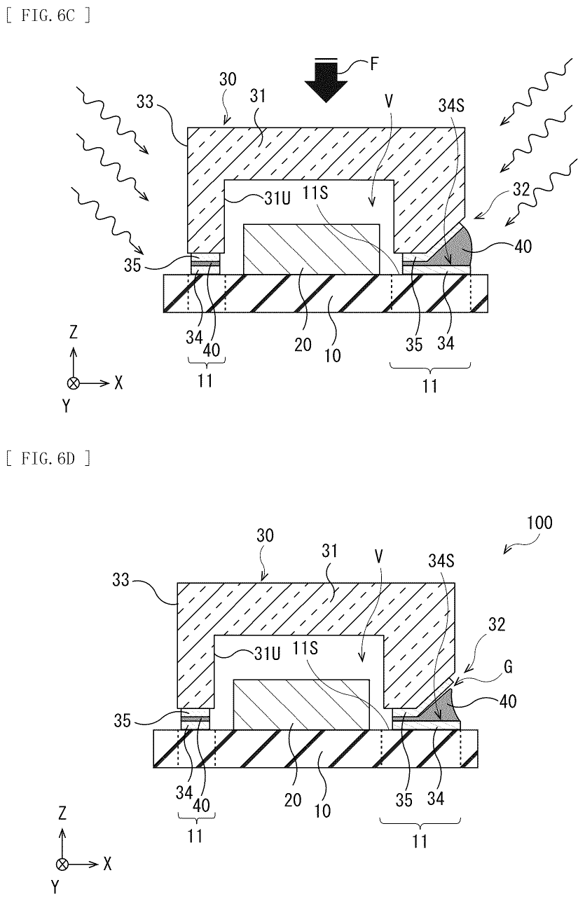

Next, a description will be given of a manufacturing method of the light emitting apparatus 100 with reference to FIGS. 6A to 6D. Note that FIGS. 6A to 6D describe how a single semiconductor laser 20 and a single cap 30 are bonded to a single base substrate 10 using the bonding member 40; however, in actuality, a plurality of semiconductor lasers 20 and a plurality of caps 30 may be formed on the same base substrate 10, following which an operation of separating into individual light emitting apparatuses 100 may be performed with a dicing blade or the like. FIGS. 6A to 6D are process flow diagrams illustrating an example of the manufacturing method of the light emitting apparatus 100.

First, as illustrated in FIG. 6A, the base substrate 10 is prepared, following which the semiconductor laser 20 is placed at a predetermined position on the base substrate 10, and the first metal layer 34 is formed on the support part 11. Meanwhile, the second metal layer 35 is formed on the opposed part 32 of the body 31, and the bonding member 40 such as solder is applied to the second metal layer 35 in advance.

Thereafter, as illustrated in FIG. 6B, the first metal layer 34 and the second metal layer 35 are so aligned as to be opposed to each other with the bonding member 40 interposed therebetween, following which the cap 30 is pressed against the base substrate 10 with a predetermined load F.

Thereafter, as illustrated in 6C, with the cap 30 kept in a state of being pressed against the base substrate 10 with the load F, the bonding member 40 is heated to thereby cause the bonding member 40 to melt. A method of heating the bonding member 40 may be a method of applying heat through heat conduction from the atmosphere, such as reflow, or a method of applying heat on a stage using a die bonder.

Thereafter, the bonding member 40 is cooled, which allows the first metal layer 34 and the second metal layer 35 to be bonded to each other by the first part 41 of the bonding member 40. As a result, the cap 30 is so fixed onto the base substrate 10 as to cover the semiconductor laser 20, and the light emitting apparatus 100 is thus completed. Note that as illustrated in 6D, at least a portion of the second part 42 is spaced from at least one of the first metal layer 34 or the second metal layer 35 to thereby form the gap G. This releases a tensile stress caused by contraction of the bonding member 40 and thus mitigates the tensile stress to propagate to the cap 30. Accordingly, damage to the cap 30, such as cracking or chipping, is avoided.

### 1.3. Working and Effects

As described above, the light emitting apparatus 100 of the present embodiment has the gap G between at least a portion of the second part 42, of the bonding member 40, that has the relatively large thickness T42 and at least one of the support part 11 or the opposed part 32, the bonding member 40 being interposed between the support part 11 and the opposed part 32 and bonding the support part 11 and the opposed part 32 to each other. This releases the tensile stress caused by expansion and contraction of the bonding member 40 occurring in the manufacturing process or upon use after the manufacture, and thus mitigates the tensile stress to be applied to the cap 30. Accordingly, damage to the cap 30, such as cracking or chipping in the vicinity of the opposed part 32, is avoided.

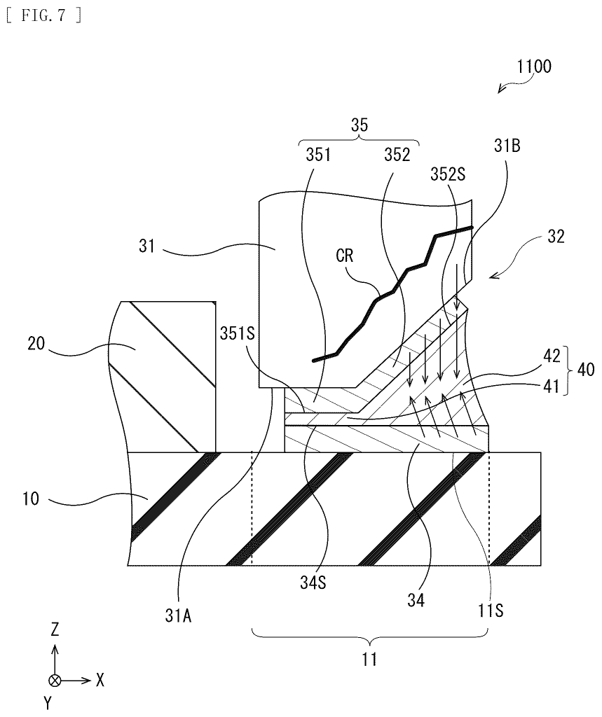

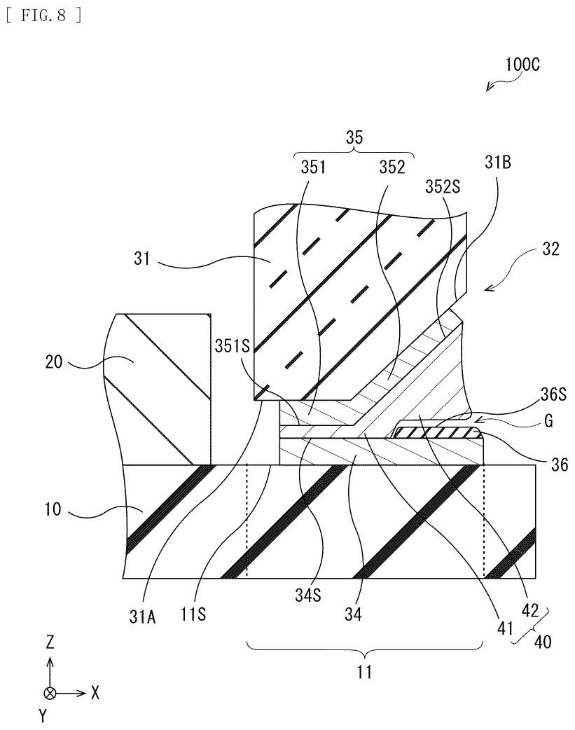

In contrast, for example, in a case where all of the second part 42 having the relatively large thickness T42 is closely bonded to the first metal layer 34 and the second metal layer 35 as in a light emitting apparatus 1100 as a reference example illustrated in FIG. 7, a difference between a coefficient of thermal linear expansion of the support part 11 and a coefficient of thermal linear expansion of the opposed part 32 would cause stress to be applied to the support part 11 and the opposed part 32 upon the occurrence of expansion and contraction of the bonding member 40 due to changes in temperature or the like. This can result in a crack CR at a location where strength is lowest, such as a portion of the body 31 that includes, for example, a glass material or the like.

To address this, in the light emitting apparatus 100 of the present embodiment, at least a portion of the second part 42 is caused to be spaced from at least one of the first metal layer 34 or the second metal layer 35 by, for example, reducing the wettability of the surface 352S of the second metal layer 35 for the bonding member 40 or the wettability, for the bonding member 40, of the portion of the surface 34S of the first metal layer 34 opposed to the second part 42 of the bonding member 40. As a result, even if expansion and contraction of the bonding member 40 occur, it is possible to effectively prevent damage to the cap 30 caused by stress associated with the expansion and contraction of the bonding member 40.

### 1.4. Modification Examples

### Third Modification Example

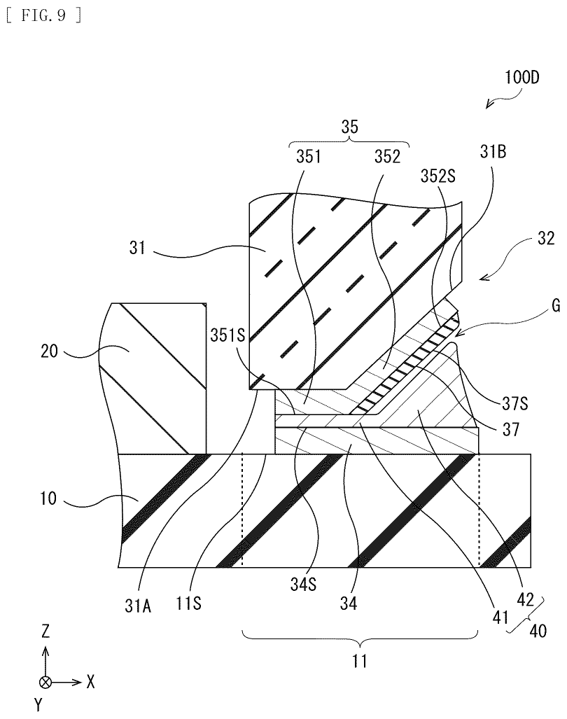

A light emitting apparatus 100C according to a third modification example of the present embodiment will be described with reference to FIG. 8. FIG. 8 is a schematic diagram illustrating a partial cross-sectional configuration example of the light emitting apparatus 100C. Note that FIG. 8 corresponds to FIG. 2 illustrating the partial cross-sectional configuration example of the light emitting apparatus 100 of the foregoing embodiment.

The light emitting apparatus 100C in FIG. 8 has a configuration substantially the same as the configuration of the light emitting apparatus 100 illustrated in, for example, FIG. 2 except that a film 36 is provided. Specifically, in the light emitting apparatus 100C, the film 36 is provided to be stacked on a portion of the surface 34S of the first metal layer 34, the film 36 having a surface 36S on an opposite side to the surface 34S. More specifically, the film 36 is provided on the surface 34S at a position opposed to the surface 352S of the second metal layer 35 with the second part 42 of the bonding member 40 interposed therebetween. Accordingly, the surface 36S of the film 36 is opposed to the surface 352S of the second metal layer 35 with the second part 42 of the bonding member 40 interposed therebetween. In the light emitting apparatus 100C, the surface 34S does not have to undergo any surface modification treatment. For example, the film 36 includes an oxide film containing at least one of SiO₂ or Al₂O₃, or a nitride film containing SiN (silicon nitride).

In the light emitting apparatus 100C, wettability of the film 36 for the bonding member 40 is lower than the wettability of the surface 34S of the first metal layer 34 for the bonding member 40. Accordingly, in the manufacturing process of the light emitting apparatus 100C, at least a portion of the second part 42 is caused to be spaced from the surface 36S to thereby form the gap G between the film 36 and the second part 42 of the bonding member 40. This releases the tensile stress caused by expansion and contraction of the bonding member 40 occurring in the manufacturing process or upon use after the manufacture, and thus mitigates the tensile stress to be applied to the cap 30. As a result, damage to the cap 30, such as cracking or chipping in the vicinity of the opposed part 32, is avoided.

### Fourth Modification Example

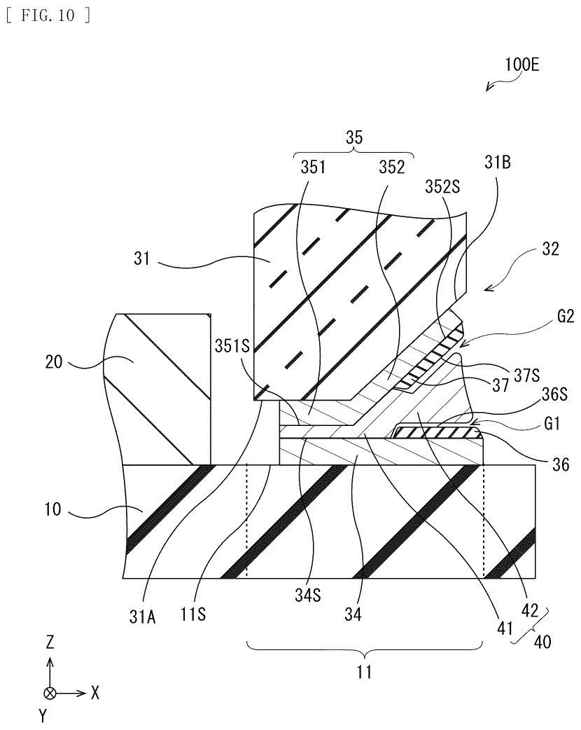

A light emitting apparatus 100D according to a fourth modification example of the present embodiment will be described with reference to FIG. 9. FIG. 9 is a schematic diagram illustrating a partial cross-sectional configuration example of the light emitting apparatus 100D. Note that FIG. 9 corresponds to FIG. 2 illustrating the partial cross-sectional configuration example of the light emitting apparatus 100 of the foregoing embodiment.

The light emitting apparatus 100D in FIG. 9 has a configuration substantially the same as the configuration of the light emitting apparatus 100 illustrated in, for example, FIG. 2 except that a film 37 is provided. Specifically, in the light emitting apparatus 100D, the film 37 is provided to cover the surface 352S of the second part 352 of the second metal layer 35, the film 37 having a surface 37S on an opposite side to the surface 352S. Accordingly, the surface 37S of the film 37 is opposed to the surface 34S of the first metal layer 34 with the second part 42 of the bonding member 40 interposed therebetween. In the light emitting apparatus 100D, the surface 352S of the second part 352 does not have to undergo any surface modification treatment. For example, the film 37 includes an oxide film containing at least one of SiO₂ or Al₂O₃, or a nitride film containing SiN (silicon nitride).

In the light emitting apparatus 100D, wettability of the film 37 for the bonding member 40 is lower than the wettability of the surface 351S of the first part 351 of the second metal layer 35 for the bonding member 40. Accordingly, in the manufacturing process of the light emitting apparatus 100D, at least a portion of the second part 42 is caused to be spaced from the surface 37S to thereby form the gap G between the film 37 and the second part 42 of the bonding member 40. This releases the tensile stress caused by expansion and contraction of the bonding member 40 occurring in the manufacturing process or upon use after the manufacture, and thus mitigates the tensile stress to be applied to the cap 30. As a result, damage to the cap 30, such as cracking or chipping in the vicinity of the opposed part 32, is avoided.

### Fifth Modification Example

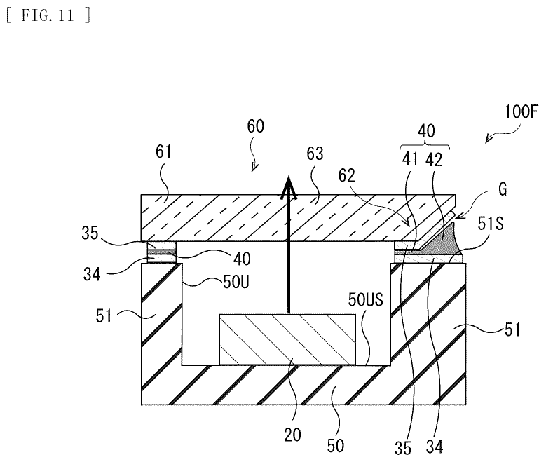

A light emitting apparatus 100E according to a fifth modification example of the present embodiment will be described with reference to FIG. 10. FIG. 10 is a schematic diagram illustrating a partial cross-sectional configuration example of the light emitting apparatus 100E. Note that FIG. 10 corresponds to FIG. 2 illustrating the partial cross-sectional configuration example of the light emitting apparatus 100E of the foregoing embodiment.

The light emitting apparatus 100E in FIG. 10 has a configuration substantially the same as the configuration of the light emitting apparatus 100 illustrated in, for example, FIG. 2 except that the film 36 and the film 37 are provided. Positions where the films 36 and 37 are to be provided, and materials, technical significance, etc. of the films 36 and 37 are the same as those in the light emitting apparatus 100C as the third modification example of the foregoing embodiment and the light emitting apparatus 100D as the fourth modification example of the foregoing embodiment.

### 2. Other Modification Examples

The technology according to the present disclosure has been described above with reference to some embodiments and modification examples. However, the technology according to the present disclosure is not limited to the above-described embodiments and the like, and is modifiable in a variety of ways.

### Sixth Modification Example

For example, in the light emitting apparatus 100 of the foregoing embodiment, the semiconductor laser 20 mounted on the base substrate 10 having a flat plate shape is covered with the cap 30 including the body 31 having the recessed part 31U. In the present disclosure, however, also employable is an embodiment like a light emitting apparatus 100F as a sixth modification example illustrated in FIG. 11, for example. In the light emitting apparatus 100F, a container 50 having a recessed part 50U is provided as a base, instead of the base substrate 10. The semiconductor laser 20 is placed on a bottom surface 50US of the recessed part 50U. The container 50 has a support part 51 including a support surface 51S. The support surface 51S makes a round to enclose the recessed part 50U in the XY plane. The light emitting apparatus 100F includes a cover part 60 including a body 61 having a substantially flat plate shape. The body 61 includes, for example, a material similar to that included in the body 31 in the light emitting apparatus 100, and includes an opposed part 62 opposed to the support part 51, and a light transmissive part 63. The semiconductor laser 20 is, for example, a surface emitting laser, and is configured to oscillate the laser light L to pass through the light transmissive part 63. The first metal layer 34 and the second metal layer 35 are provided between the support part 51 and the opposed part 62, and the first metal layer 34 and the second metal layer 35 are bonded to each other via the bonding member 40. Note that as in the light emitting apparatus 100 described above, the bonding member 40 includes the first part 41, and the second part 42 that is larger in thickness than the first part 41. The gap G is present between at least a portion of the second part 4 and at least one of the support part 51 or the opposed part 62. Accordingly, effects similar to those of the light emitting apparatus 100 in FIG. 2 or the like are also expectable from the light emitting apparatus 100F in FIG. 11.

Further, in the light emitting apparatus 100 of the foregoing embodiment and the like, the support part includes the first metal layer 34 and the opposed part includes the second metal layer 35; however, the present disclosure is not limited to such an embodiment. In other words, the light emitting apparatus of the present disclosure may include neither the first metal layer 34 nor the second metal layer 35. A gap may be provided between the second part 42 of the bonding member 40 and at least one of a portion of the surface 11S or the surface 31B of the body 31 of the cap 30 by, for example, applying surface modification treatment to the portion of the surface 11S or applying surface modification treatment to the surface 31B of the body 31.

In addition, not all of the configurations and the operations described in the foregoing embodiment and each of the modification examples are indispensable as the configurations and the operations of the present disclosure. For example, among the components of each embodiment, any component that is not recited in an independent claim which represents the most generic concept of the present disclosure is to be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used herein include terms that are used merely for convenience of description and that are not used to limit the configuration and the operation. For example, the terms such as “right”, “left”, “upper”, and “lower” only indicate directions in the drawings being referred to. In addition, the terms “inside” and “outside” only indicate a direction toward the center of a component of interest and a direction away from the center of a component of interest, respectively. The same applies to terms similar to these and to terms with the similar purpose.

It is to be noted that the technology according to the present disclosure may have the following configurations. The light emitting apparatus according to one embodiment of the present disclosure having the following configurations has a structure that is suitable for miniaturization and easily manufacturable.

Note that effects attained by the technology according to the present disclosure are not necessarily limited to the effects described here, and may include any of the effects described in the present disclosure.
<1>

A light emitting apparatus including:

a base including a support part that includes a support surface;

a light emitting device provided on the base and emitting light;

a cover part provided on the support part to cover the light emitting device, and including an opposed part opposed to the support part and a light transmissive part that transmits the light emitted from the light emitting device; and

a bonding member interposed between the support part and the opposed part and bonding the support part and the opposed part to each other, in which

the bonding member includes a first part having a first thickness and a second part having a second thickness larger than the first thickness, and

the light emitting apparatus has a gap between at least a portion of the second part and at least one of the support part or the opposed part.
<2>

The light emitting apparatus according to <1>, in which

the opposed part includes an opposed surface extending along the support surface, and an inclined surface inclined with respect to the opposed surface,

the first part is interposed between the opposed surface and the support surface,

the second part is interposed between the inclined surface and the support surface, and at least the portion of the second part is spaced from at least one of the inclined surface or the support surface.
<3>

The light emitting apparatus according to <2>, in which wettability of the inclined surface for the bonding member is lower than wettability of the opposed surface for the bonding member.
<4>

The light emitting apparatus according to any one of <1> to <3>, in which

the support part includes a first metal layer, and

the opposed part includes a second metal layer opposed to the first metal layer with the bonding member interposed therebetween.
<5>

The light emitting apparatus according to <2>, in which

the support part includes
a first metal layer including a first surface as the support surface, the first surface being opposed to the opposed surface with the first part interposed therebetween, and
a first film stacked on a portion of the first metal layer and opposed to the inclined surface with the second part interposed therebetween.
<6>

The light emitting apparatus according to <5>, in which the opposed part includes a second metal layer including a third surface as the opposed surface, and a second film stacked on a portion of the second metal layer and including a fourth surface as the inclined surface.
<7>

The light emitting apparatus according to <6>, in which at least the portion of the second part is spaced from at least one of the second surface or the fourth surface.
<8>

The light emitting apparatus according to <6> or <7>, in which the first film and the second film each include an oxide film containing at least one of SiO₂ or Al₂O₃, or a nitride film containing SiN (silicon nitride).
<9>

The light emitting apparatus according to any one of <1> to <8>, in which a coefficient of thermal linear expansion (CTE) of the bonding member is higher than a coefficient of thermal linear expansion of the cover part.
<10>

The light emitting apparatus according to any one of <1> to <9>, in which the bonding member includes solder, a resin adhesive, an electrically-conductive adhesive, or a low-melting-point glass.
<11>

The light emitting apparatus according to <2>, in which the opposed surface and the inclined surface are provided at positions in the cover part that are off an optical path along which the light from the light emitting device travels.

The present application claims the benefit of Japanese Priority Patent Application JP2023-008104 filed with the Japan Patent Office on Jan. 23, 2023, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light emitting apparatus comprising:
a base including a support part that includes a support surface;
a light emitting device provided on the base and emitting light;
a cover part provided on the support part to cover the light emitting device, and including an opposed part opposed to the support part and a light transmissive part that transmits the light emitted from the light emitting device; and
a bonding member interposed between the support part and the opposed part and bonding the support part and the opposed part to each other, wherein
the bonding member includes a first part having a first thickness and a second part having a second thickness larger than the first thickness, and
the light emitting apparatus has a gap between at least a portion of the second part and at least one of the support part or the opposed part.

2. The light emitting apparatus according to claim 1, wherein
the opposed part includes an opposed surface extending along the support surface, and an inclined surface inclined with respect to the opposed surface,
the first part is interposed between the opposed surface and the support surface,
the second part is interposed between the inclined surface and the support surface, and
at least the portion of the second part is spaced from at least one of the inclined surface or the support surface.

3. The light emitting apparatus according to claim 2, wherein wettability of the inclined surface for the bonding member is lower than wettability of the opposed surface for the bonding member.

4. The light emitting apparatus according to claim 1, wherein
the support part includes a first metal layer, and
the opposed part includes a second metal layer opposed to the first metal layer with the bonding member interposed therebetween.

5. The light emitting apparatus according to claim 2, wherein
the support part includes
a first metal layer including a first surface as the support surface, the first surface being opposed to the opposed surface with the first part interposed therebetween, and
a first film stacked on a portion of the first metal layer and opposed to the inclined surface with the second part interposed therebetween.

6. The light emitting apparatus according to claim 5, wherein the opposed part includes a second metal layer including a third surface as the opposed surface, and a second film stacked on a portion of the second metal layer and including a fourth surface as the inclined surface.

7. The light emitting apparatus according to claim 6, wherein at least the portion of the second part is spaced from at least one of the second surface or the fourth surface.

8. The light emitting apparatus according to claim 6, wherein the first film and the second film each comprise an oxide film containing at least one of SiO₂ or Al₂O₃, or a nitride film containing SiN (silicon nitride).

9. The light emitting apparatus according to claim 1, wherein a coefficient of thermal linear expansion (CTE) of the bonding member is higher than a coefficient of thermal linear expansion of the cover part.

10. The light emitting apparatus according to claim 1, wherein the bonding member comprises solder, a resin adhesive, an electrically-conductive adhesive, or a low-melting-point glass.

11. The light emitting apparatus according to claim 2, wherein the opposed surface and the inclined surface are provided at positions in the cover part that are off an optical path along which the light from the light emitting device travels.
